(19) United States
(12) Patent Application Publication
(10) Pub. No.: US 2008/0079829 A1
(43) Pub. Date: Apr. 3, 2008

(54) Camera module and method for manufacturing same

(75) Inventors: Yong-Hwan Choi, Suwon-si (KR); Young-Kwon Yoon, Seoul (KR)

Correspondence Address: CHA & REITER, LLC, 210 ROUTE 4 EAST STE 103, PARAMUS, NJ, 07652, US

(73) Assignee: Samsung Electronics Co.; LTD

(21) Appl. No.: 11/893,812

(22) Filed: Aug. 17, 2007

(30) Foreign Application Priority Data
Sep. 28, 2006 (KR) 2006-94767

(51) Int. Cl. H04N 5/335; H01L 21/00

(52) U.S. Cl. 348/294; 438/64; 438/65; 257/E21.001; 348/E05.091

(57) ABSTRACT

Disclosed is a camera module and a method of manufacture. The camera module includes a ceramic printed circuit board having a recess formed on its upper surface, an image sensor seated in the recess, a flexible printed circuit board positioned on the image sensor and electrically connected to the image sensor and a cap seated on the ceramic printed circuit board, the cap having a lens system positioned on a surface facing the image sensor. A method for manufacturing the camera module includes the steps of flip-chip-bonding an image sensor to a lower portion of a flexible printed circuit board, forming a ceramic printed circuit board having a recess; mounting the image sensor in the recess of the ceramic printed circuit board and seating a cap on the ceramic printed circuit board.

### CLAIM OF PRIORITY

This application claims the benefit of the earlier filing date, pursuant to 35 USC 119, to that patent an application entitled “Camera Module and Method for Manufacturing the Same,” filed with the Korean Intellectual Property Office on Sep. 28, 2006 and assigned Serial No. 2006-94767, the contents of which are incorporated herein by reference.

### BACKGROUND OF THE INVENTION

1. Field of the Invention

The present invention relates to a camera module, and more particularly to a camera module including an image sensor.

2. Description of the Related Art

Recent development of digital and semiconductor technologies has caused the widespread use of digital cameras and camera modules that have CCD- or CMOS-type image sensors. The digital cameras and camera modules can be easily carried and conveniently operated. For at least this reason, digital cameras and modules have been incorporated into portable communication terminals and other types of digital devices.

Particularly, the fact that camera modules are incorporated by compact digital devices and portable communication terminals increases the pressure to reduce their size.

FIG. 1 is a sectional view of a conventional camera module. FIG. 1 shows the section of a camera module manufactured in a known “chip-on-board” method. Referring to FIG. 1, the camera module 100 includes a printed circuit board 120, an image sensor 130 seated on the printed circuit board 120 and electrically connected to printed circuit board 120 by wire bonding 101 and 102, a flexible printed circuit board 110 connected to the lower portion of the printed circuit board 120 and a cap 140 seated on the printed circuit board 120.

A connector 221 is positioned on an end of the flexible printed circuit board 110 for connection to a main board of a portable terminal or a corresponding device.

The cap 140 has an opening formed on its top so that light can be incident on the image sensor 130. A lens system 150 is mounted in the opening. An optical filer 160 may be positioned between the lens system 150 and the image sensor 130.

Since the image sensor 130 is wire-bonded to electric terminals 121 formed on the upper surface of the printed circuit board 120, this type of camera module 100 can be manufactured by process technology similar to conventional semiconductor manufacturing processes while maintaining stable productivity.

However, conventional camera modules have a problem in that they need a space for wire bonding. This limits their application to portable communication terminals and digital devices; as these devices are getting slimmer. Particularly, chip-on-board-type camera modules require a space for wire bonding between the image sensor and the electric terminals, as well as a space between the electric terminals and the cap. In addition, their thickness increases as much as that of the image sensor mounted on the upper surface of the printed circuit board.

### SUMMARY OF THE INVENTION

Accordingly, the present invention has been made to solve the above-mentioned problems occurring in the prior art and provides additional advantages, by providing a camera module adapted for an ultra-slim portable communication terminal or digital device.

According to an aspect of the present invention, there is provided a camera module including a ceramic printed circuit board, a recess being formed on an upper surface of the ceramic printed circuit board; an image sensor seated in the recess, a flexible printed circuit board positioned on the image sensor and electrically connected to the image sensor and a cap seated on the ceramic printed circuit board, the cap having a lens system facing the image sensor.

In accordance with another aspect of the present invention, there is provided a method for manufacturing a camera module, the method including the steps of flip-chip-bonding an image sensor to a lower portion of a flexible printed circuit board, forming a ceramic printed circuit board having a recess, mounting the image sensor in the recess of the ceramic printed circuit board and seating a cap on the ceramic printed circuit board.

### BRIEF DESCRIPTION OF THE DRAWINGS

The above features, and advantages of the present invention will be more apparent from the following detailed description taken in conjunction with the accompanying drawings, in which:

FIG. 1 shows the sectional structure of a conventional camera module;

FIG. 2 shows the sectional structure of a camera module according to an exemplary embodiment of the present invention; and

FIGS. 3A to 3C show the sectional structure of the camera module shown in FIG. 2 in respective manufacturing steps.

### DETAILED DESCRIPTION OF THE INVENTION

Hereinafter, an exemplary embodiment of the present invention will be described with reference to the accompanying drawings. For the purposes of simplicity and clarity, a detailed description of known functions and configurations incorporated herein is omitted to avoid making the subject matter of the present invention unclear.

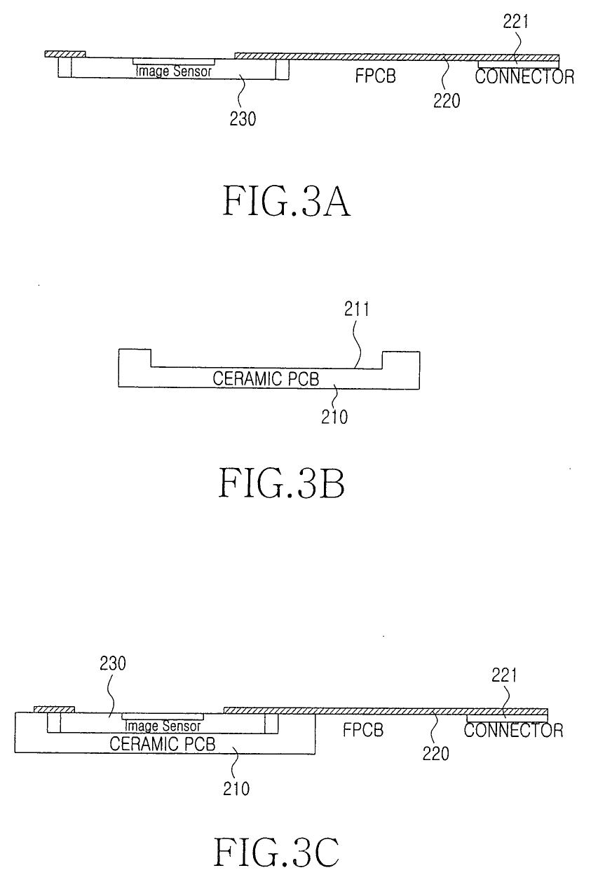

FIG. 2 shows the sectional structure of a camera module according to an exemplary embodiment of the present invention, and FIGS. 3A to 3C show the sectional structure of the camera module shown in FIG. 2 in respective manufacturing steps. Referring to FIG. 2, the camera module 200 according to the present invention includes a ceramic printed circuit board 210 having a recess formed on its upper surface, an image sensor 230 seated in the recess, a flexible printed circuit board 220 positioned on the image sensor 230 and electrically connected to it and a cap 240 seated on the ceramic printed circuit board 210 including a lens system 250 positioned on a surface facing the image sensor 230.

The ceramic printed circuit board 210 has a recess formed thereon so as to secure a space in which the image sensor 230 is seated. The recess has a depth large enough to receive the image sensor 230.

The ceramic printed circuit board 210 may be made of alumina (Al₂0₃), beryllia (BeO), forsterite, steatite, or mullite. In particular, alumina is preferably used due to its excellent mechanical properties, thermal conductivity, and adhesiveness, besides the fact that is not harmful to human bodies.

The ceramic printed circuit board 210 is obtained by laminating a plurality of green tapes, which have circuit patterns printed thereon, so as to form a laminate, and sintering the laminate at a temperature of 1000° C. or lower into a desired shape. When the laminate of green tapes is sintered, the circuit patterns may be damaged by sintering contraction. In order to prevent this, a metal substrate is placed beneath the laminate so that the ceramic substrate and the metal are bonded to each other.

The image sensor 230 may be electrically connected to the flexible printed circuit board 220 by flip-chip bonding or ultrasonic bonding. The flexible printed circuit board 220 has a through-hole formed therein so that light can propagate between the lens system 250 and the image sensor 230. The image sensor 230 may be electrically connected to the ceramic printed circuit board 210 by ultrasonic bonding.

Epoxy is applied to the portion of the ceramic printed circuit board 210, on which the image sensor 230 is to be seated, for attachment of the image sensor 230. The image sensor 230 and the flexible printed circuit board 220 may be attached to the ceramic printed circuit board 210 by flip-chip or ultrasonic bonding. The flip-chip bonding method has the advantage of excellent electric performance and reduction in product size. According to the flip-chip bonding method, bumps are placed on electric terminals, which are metal pads made of aluminum, for example, and the bumps (i.e. metal mediators) are connected to connection terminals of the substrate by Anisotropic Conductive Film (ACF) or Non-Conductive Paste (NCP), for example.

During the flip-chip bonding method, the bumps are formed by vacuum deposition, screen printing of solder paste, wire bonding, electroplating, or electroless plating.

In the case of the vacuum deposition, metal is vaporized in a vacuum chamber so as to deposit metallic bumps. This method is applicable when there are many metal electrodes or pins for flip-chip bonding. Bump formation based on the electroplating includes photolithography, plating, and etching processes. According to electroless plating, which is contrasted with the electroplating, the pad surface is subjected to zincate treatment. Typically, Ni bumps are formed by electroless plating, and their upper surface is plated, for example, with gold.

As mentioned above, the recess of the ceramic printed circuit board 210, into which the image sensor 230 is to be inserted, has a depth corresponding to the thickness of the image sensor 230 so that the image sensor 230 when seated on the ceramic printed circuit board 210 is flush with the ceramic printed circuit board 210. Therefore, the flexible printed circuit board 220 can be seated on the ceramic printed circuit board 210 at the same time the image sensor 230 is seated on the ceramic printed circuit board 210.

The cap 240 has an opening formed on a part of its surface facing the image sensor 230 so that the lens system 250 is inserted and fixed in the opening. An optical filter 260 is retained between the lens system 250 and the image sensor 230. The optical filter 260 may be a near infrared-coated filter or a wavelength band selection filter.

Referring to FIGS. 3A to 3c, a method for manufacturing a camera module according to the present invention includes the steps of flip-chip-bonding an image sensor 230 to the lower portion of a flexible printed circuit board 220, forming a recess on a ceramic printed circuit board 210 so that the image sensor 230 can be mounted therein, mounting the image sensor 230 in the recess of the ceramic printed circuit board 210 and seating a cap 240 on the ceramic printed circuit board 210.

As shown in FIG. 3A, the image sensor 230 is electrically connected to the flexible printed circuit board 220 by flip-chip bonding or ultrasonic bonding. A recess is formed on the ceramic printed circuit board 210 as shown in FIG. 3B. Metal patterns are formed on respective bonding surfaces of the ceramic printed circuit board 210 and the image sensor 230 so that by applying ultrasonic vibration, the ceramic printed circuit board 210 and the image sensor 230 are forced against each other.

The image sensor 230 is seated within the ceramic printed circuit board 210 after a recess is formed thereon, as shown in FIG. 3A. The cap 240 is seated on the ceramic printed circuit board 210 opposite the image sensor 230, as shown in FIG. 2.

The flexible and ceramic printed circuit boards 220 and 210 can be coupled to each other at the same time the image sensor 230 is seated within the ceramic printed circuit board 210. A connector 221 may be positioned on an end of the flexible printed circuit board 220.

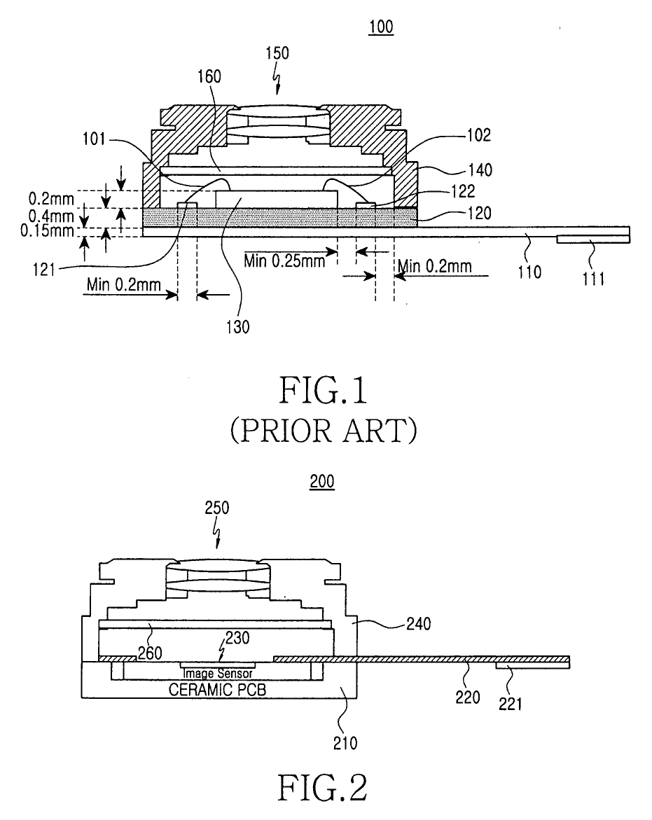

Referring to FIG. 1, which shows a conventional hot-bar-type camera module 100, the printed circuit board 120 itself has a typical thickness of 0.4 mm, the image sensor 130, which is seated on the upper surface of the printed circuit board 120, has a thickness of 0.2 mm and the flexible printed circuit board 110 has a thickness of 0.15 mm. The total thickness from the image sensor 130 to the flexible printed circuit board 110 is in the order of 0.75 mm. Furthermore, the conventional camera module 100 requires an additional space (typically 0.65 mm) for wire-bonding the image sensor 130 onto the printed circuit board 120.

More particularly, the electric terminals 121 and 122 connected to the printed circuit board 120 by wire bonding require a length of at least 0.2 mm, and the image sensor 130 must be spaced from the electric terminals 121 and 122 by at least 0.25 mm. In addition, the cap 140 must be spaced from the electric terminals 121 and 122 by at least 0.2 mm. The total length necessary for wire bonding is in the order of 1.3 mm.

In contrast, the camera module 200 according to the present invention can minimize the thickness of the ceramic printed circuit board 210 to 0.4 mm by forming a recess on the ceramic printed circuit board 210 and seating the image sensor 230 in the recess. An interval of at least 0.1 mm must be secured between the lateral surfaces of the recess of the ceramic printed circuit board 210 and the image sensor 230, and a distance of at least 0.2 mm is necessary between the cap 240 and the recess. Therefore, the inventive camera module 200 has a minimum thickness of 0.4 mm and a minimum width corresponding to the width of the image sensor plus 0.6 mm (0.3 mm×2).

In summary, the camera module according to the present invention has significantly less thickness and length than the conventional camera modules.

While the invention has been shown and described with reference to certain embodiments, which are preferred, it will be understood by those skilled in the art that various changes in form and details may be made therein without departing from the spirit and scope of the invention as defined by the appended claims. For example, the method described herein of mounting, enclosing or encapsulating a sensor module within a recess contained in a PCB in order to reduce the thickness of the combination of the PCB and sensor is also applicable to other devices.

What is claimed is:

1. A camera module comprising:
a ceramic printed circuit board,
a recess being formed on an upper surface of the ceramic printed circuit board; and
an image sensor seated in the recess.

2. The camera module as claimed in claim 1, further comprising:
a flexible printed circuit board positioned on the image sensor and electrically connected to the image sensor; and
a cap seated on the flexible printed circuit board, the cap having a lens system positioned on a surface facing the image sensor.

3. The camera module as claimed in claim 2, wherein the cap further includes an optical filter positioned between the lens system and the image sensor.

4. The camera module as claimed in claim 2, wherein an opening is formed in the flexible printed circuit board so light can propagate between the lens system and the image sensor.

5. The camera module as claimed in claim 2, wherein the image sensor is connected to the flexible printed circuit board by ultrasonic bonding.

6. The camera module as claimed in claim 1, wherein the image sensor is electrically connected to the ceramic printed circuit board by ultrasonic bonding.

7. The camera module as claimed in claim 3, wherein the optical filter is selected from the group consisting of: near infrared filter and a wavelength band selection filter.

8. The camera module as claimed in claim 2, wherein a connector is positioned on an end of the flexible printed circuit board.

9. A method for manufacturing a camera module, the method comprising the steps of:
flip-chip-bonding an image sensor to a lower portion of a flexible printed circuit board, said flexible printed circuit board having a hole to allow light to pass to said sensor;
forming a ceramic printed circuit board having a recess therein;
mounting the ceramic printed circuit board to the flexible printed circuit board to enable the image sensor to be contained within the recess; and
seating a cap on the flexible printed circuit board.

10. The method as claimed in claim 9, wherein the image sensor is electrically connected to the ceramic printed circuit board by ultrasonic bonding.

11. The method as claimed in claim 9, wherein a lens system is mounted on a surface of the cap, the surface facing the image sensor.

12. The method as claimed in claim 9, wherein an optical filter is mounted between the image sensor and the lens system of the cap.

13. A module comprising:
a sensor mounted to a first side of a printed circuit board; and
a ceramic printed circuit board having a recess contained therein mounted to said printed circuit board, said sensor being contained within said recess; and
a cap mounted to a second side of said printed circuit board.

14. The module as claimed in claim 13, wherein said printed circuit board includes a hole to enable light to pass to said sensor.

15. The module as claimed in claim 13, wherein said sensor is ultrasonic bonded to said printed circuit board.

16. The module as claimed in claim 13, wherein said sensor is wire-bonded to said printed circuit board.

17. The module as claimed in claim 13, wherein said cap comprises:
a lens assembly.

18. The module as claimed in claim 17, wherein said cap further comprises:
a filter assembly imposed between said lens assembly and said sensor.

19. The module as claimed in claim 18, wherein said filter assembly is selected from the group consisting of: near infrared filter and a wavelength band selection filter.

20. The module as claimed in claim 13, wherein said sensor is ultrasonic bonded to said ceramic printed circuit board.

21. The module as claimed in claim 13, wherein said sensor is wire-bonded to said ceramic printed circuit board.
